(19) United States
(12) Patent Application Publication
(10) Pub. No.: US 2018/0051369 A1
(43) Pub. Date: Feb. 22, 2018

(54) Apparatus for Evaporating a Material

(71) Applicant: NuvoSun, Inc., Milpitas, CA (US)

(72) Inventors: Bruce D. HACHTMANN, San Martin, CA (US); Karnig Ross Baron PORTER, Cambridge, MA (US); Aaron A. QUITUGUA-FLORES, Palo Alto, CA (US); Arthur C. WALL, Morgan Hill, CA (US)

(21) Appl. No.: 15/561,129

(22) PCT Filed: Mar. 17, 2016
(86) PCT No.: PCT/US2016/022989

§ 371 Date: Sep. 25, 2017

Related U.S. Application Data
(60) Provisional application No. 62/136,831, filed on Mar. 23, 2015.

(51) Int. Cl. C23C 14/24; C23C 14/56; C23C 14/54; C23C 14/06; H01L 31/0216; H01L 31/0392

(52) U.S. Cl. CPC C23C 14/243; C23C 14/562; C23C 14/566; H01L 31/03923; C23C 14/542; C23C 14/0623; H01L 31/02167; C23C 14/541

(57) ABSTRACT

An example apparatus for depositing a predetermined amount of a material onto a substrate includes a container having a cavity configured to contain the material. The container and the cavity are elongated along a first axis of the container. The apparatus further includes one or more heaters that are (i) elongated along the first axis and (ii) configured to heat and evaporate the material by heating the container. The apparatus further includes a conveyor for moving the substrate in a direction substantially perpendicular to the first axis of the container and one or more openings in the container distributed along the first axis. The one or more openings provide fluid communication between a region external to the container and the cavity. A process for depositing the predetermined amount of the material onto the substrate is also disclosed herein.

### CROSS-REFERENCE TO RELATED APPLICATION

This application claims priority to U.S. Provisional Application No. 62/136,831, filed Mar. 23, 2015, the disclosure of which is hereby incorporated by reference in its entirety.

### BACKGROUND

### Field of the Invention

The disclosure relates to apparatus for evaporating materials, such as for use in the manufacture of solar cells.

### Description of Related Art

Unless otherwise indicated herein, the materials described in this section are not prior art to the claims in this application and are not admitted to be prior art by inclusion in this section.

Solar cells typically include a material that generates charge carriers in response to absorption of light. One such light-absorbing material is Cu(In,Ga)Se2 (CIGS). Introducing a controlled amount of sodium into CIGS (or a similar light-absorbing material) may passivate grain boundaries within the material. This reduces the amount of carrier recombination centers within the material, leading to increased solar cell efficiency as more generated charge carriers are collected before recombination.

One such process for introducing sodium into CIGS is to deposit CIGS (and perhaps other material layers) upon soda-lime glass to form a substrate, and during the process, heating the substrate to cause the sodium present in the soda-lime glass to diffuse into the CIGS layer. For material uniformity and repeatability, this method may be undesirable since it can be difficult to control material diffusion through metal layers. For this reason, this process does not scale up well for manufacturing large-area substrates.

Another process for introducing sodium into CIGS is to place a sodium-containing material (e.g., NaF, Na2Se, or Na2O) into a container, and then to heat the container so that the material evaporates or sublimates, resulting in the sodium-containing material being deposited upon a substrate that includes a CIGS layer above the container. This process also has not scaled up well for processing of large-area substrates due to the difficulty of evaporating and depositing a uniform amount of a sodium-containing material across a large-area substrate. Other processes for introducing sodium into CIGS films also suffer from difficulty in introducing uniform amounts of sodium into a large-area substrate.

### SUMMARY

Example embodiments provide apparatuses and processes for depositing a predetermined amount of a material onto a substrate. Further, the embodiments allow for depositing a substantially uniform thickness of the material over a large-area substrate. The embodiments involve a substantially enclosed container having a cavity configured to contain the material. The substantially enclosed container, when heated under vacuum conditions, facilitates formation of a pressure differential between the cavity and a region external to the container. In accordance with the pressure differential, vacuum conditions exist in the region external to the container while a pressure sufficient for the material to form a liquid phase is present within the cavity. The elevated pressure within the cavity enable the material to be evaporated, instead of sublimated, onto the substrate above the container.

In one example, a process for depositing a predetermined amount of a material onto a substrate includes providing a container having a cavity. The container and the cavity are elongated along a first axis of the container and the container is located within a vacuum chamber. The container includes one or more openings distributed along the first axis, where the one or more openings provide fluid communication between the cavity and a region within the vacuum chamber that is external to the container. The process further includes inserting the material into the cavity of the container and heating the container, whereby the predetermined amount of the material evaporates and exits the container via the one or more openings. The process further includes moving the substrate above the one or more openings along a second axis of the container that is substantially perpendicular to the first axis, thereby depositing the predetermined amount of the material onto the substrate.

In another aspect, an example apparatus for depositing a predetermined amount of a material onto a substrate includes a container having a cavity configured to contain the material. The container and the cavity are elongated along a first axis of the container. The apparatus further includes one or more heaters that are (i) elongated along the first axis and (ii) configured to heat and evaporate the material by heating the container. The apparatus further includes a conveyor for moving the substrate in a direction substantially perpendicular to the first axis of the container. The apparatus further includes one or more openings in the container distributed along the first axis, where the one or more openings provide fluid communication between a region external to the container and the cavity.

These as well as other aspects, advantages, and alternatives, will become apparent to those of ordinary skill in the art by reading the following detailed description, with reference where appropriate to the accompanying drawings.

### BRIEF DESCRIPTION OF THE DRAWINGS

FIG. 1 is a cross-section view of an example substrate.

FIG. 2 is a simplified cross-section view of an example apparatus for depositing a material onto a substrate.

FIG. 3 is a simplified cross-section view of another example apparatus for depositing a material onto a substrate.

FIG. 4 is an end perspective view of an example container and example heaters for depositing a material onto a substrate.

FIG. 5 is an end perspective view of an example container and example heaters for depositing a material onto a substrate.

FIG. 6 is an end perspective view of an example container and example heaters for depositing a material onto a substrate.

FIG. 7 is an end perspective view of an example container and example heaters for depositing a material onto a substrate.

FIG. 8 is a flow chart depicting an example process.

### DETAILED DESCRIPTION

Example processes and apparatuses are described herein. Any example embodiment or feature described herein is not necessarily to be construed as preferred or advantageous over other embodiments or features. The example embodiments described herein are not meant to be limiting. It will be readily understood that certain aspects of the disclosed apparatuses and processes can be arranged and combined in a wide variety of different configurations, all of which are contemplated herein.

Furthermore, the particular arrangements shown in the Figures should not be viewed as limiting. It should be understood that other embodiments may include more or less of each element shown in a given Figure. Further, some of the illustrated elements may be combined or omitted. Yet further, an example embodiment may include elements that are not illustrated in the Figures.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

As noted above, it may be useful to introduce a dopant material such as sodium into a light-absorbing material such as CIGS so that solar cells with increased efficiency can be fabricated using the doped light-absorbing material. Processing of solar cell substrates typically takes place under vacuum conditions to prevent contaminants in the atmosphere from being introduced into the substrate. Vacuum conditions cause many materials such as NaF, Na₂Se, and Na₂O to sublimate when sufficiently heated, as opposed to melting and evaporating. However, depositing a uniform thickness of a material over the area of a substrate is easier to achieve by evaporating the material from its source instead of sublimating it. The substantially enclosed container disclosed herein alleviates this problem by maintaining an elevated pressure within the container when the material inside the container is sufficiently heated. The pressure is elevated with respect to the pressure of a vacuum chamber that houses the container during processing. The pressure differential enables evaporation of the material and equilibration of the vapor inside the container or cavity and causes the evaporated material to diffuse toward the substrate above.

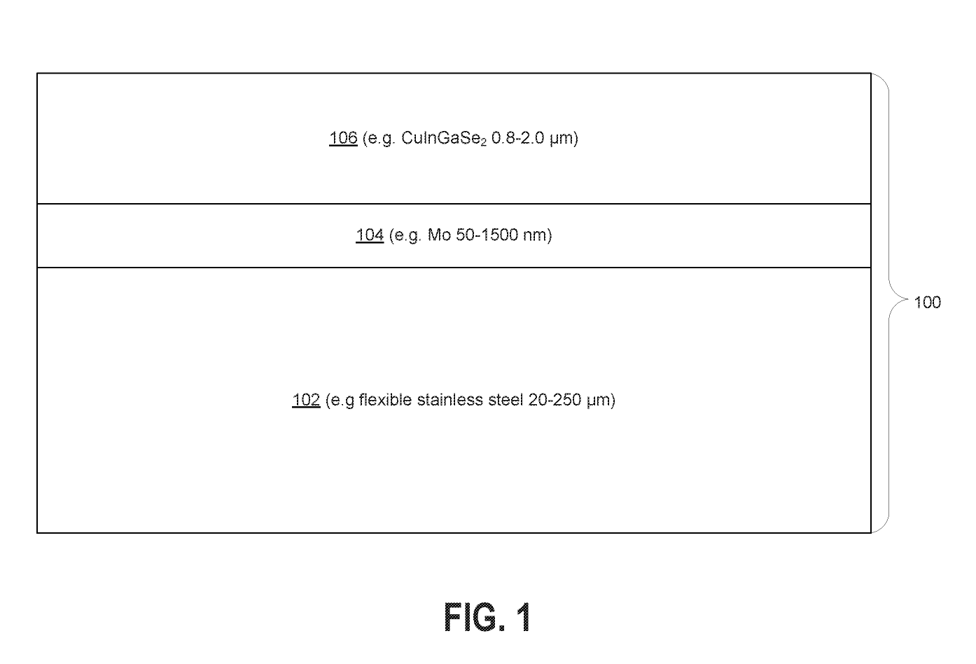

FIG. 1 illustrates an example substrate 100. The substrate 100 includes a stainless steel layer 102, a molybdenum (Mo) layer 104, a CIGS layer 106, and an iron(Fe)-blocking layer 108. In some examples, the Mo layer 104 with thickness of approximately 50-1500 nm is deposited upon the Fe-blocking layer 108 having a thickness of approximately 50-500 nm. The Fe-blocking layer 108 may be deposited upon the stainless steel layer 102 having a thickness of approximately 20-250 μm. Further, the CIGS layer 106 having a thickness of approximately 0.8-2.0 μm may be deposited upon the Mo layer 104. The Fe-blocking layer 108 may be made up of chromium and/or titanium (or other suitable metals) that help prevent Fe from the stainless steel layer 102 from diffusing into the Mo layer 104 and/or the CIGS layer 106 during high-temperature processing. The substrate 100 may undergo further processing and/or deposition of additional material layers, such as deposition of a buffer layer of cadmium sulfide, a transparent conductive oxide layer such as aluminum doped zinc oxide, or a metal contact grid layer such as nickel, aluminum, silver, or copper. One example of an additional process includes evaporating sodium or a sodium-containing material onto the CIGS layer 106 of the substrate 100. Variants of this process are described below in detail.

The substrate 100 is described above for illustrative purposes only. The apparatuses or processes described herein may involve depositing any type of material onto any type of substrate.

In one example (not shown), the CIGS layer 106 might not be initially present on the substrate. An evaporated sodium-containing material may be deposited directly upon the Mo layer 104 using the process and apparatus described herein. The CIGS layer 106 may then be deposited onto the sodium-containing material while the sodium-containing material is heated, causing diffusion of the sodium-containing material into the CIGS layer 106.

In another example (not shown), a CuInGa precursor layer is deposited on top of the Mo layer 104. This precursor layer may or may not contain some amount of selenium (Se). Then, the sodium-containing material is evaporated and deposited upon the CuInGa precursor layer. Finally, a CIGS layer is formed by heated selenization of the CuInGa precursor layer. The heated selenization causes the sodium-containing material to diffuse throughout the CIGS layer as it is being formed.

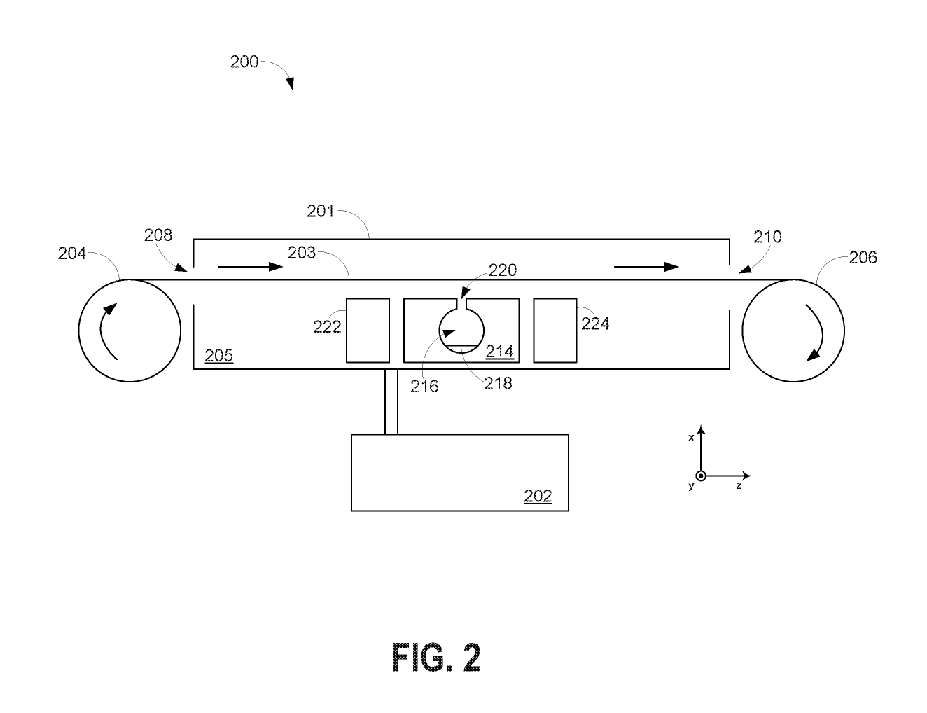

FIG. 2 illustrates an apparatus 200 for depositing a material 218 onto a substrate 203. The apparatus 200 may include a container 214 that includes a cavity 216 and one or more openings 220. The apparatus may further include heaters 222 and 224, and a conveyor comprising a feeding reel 204 and a collection reel 206. FIG. 2 also illustrates a pump 202, and a vacuum chamber 201 that includes an external region 205, an insertion point 208, and a removal point 210.

In some examples, the material 218 includes mixtures or compounds that include sodium or potassium, such as sodium fluoride (NaF), potassium fluoride (KF), sodium selenide (Na₂Se), or sodium oxide (Na₂O). In one particular example, the material 218 is in powder form.

The vacuum chamber 201 may include any chamber or container suitable for maintaining vacuum conditions inside the vacuum chamber 201 while ambient atmospheric conditions prevail outside of the vacuum chamber 201. For example, the vacuum chamber 201 may be configured to maintain a pressure of less than 10⁻² Torr within the vacuum chamber 201 while the pressure outside of the vacuum chamber 201 is approximately 760 Torr. As an example, the vacuum chamber 201 is a steel chamber or a glass chamber.

The pump 202 may be fluidly coupled to the vacuum chamber 201 to evacuate the vacuum chamber 201 so that vacuum conditions exist within the vacuum chamber 201. The pump 202 may include one or more mechanical pumps, turbo-molecular pumps, diffusion pumps, ion pumps, or cryopumps, among other possibilities.

The insertion point 208 of the vacuum chamber 201 may include a feedthrough suitable for inserting the substrate 203 into the vacuum chamber 201 while maintaining vacuum conditions inside the vacuum chamber 201. Similarly, the removal point 210 of the vacuum chamber 201 may include a feedthrough suitable for removing the substrate 203 from the vacuum chamber 201 while maintaining vacuum conditions inside the vacuum chamber 201. (In some examples, the vacuum chamber 201 may contain the entirety of the apparatus 200, and such sealed feedthroughs may not be necessary. In other examples, the feeding reel 204 and/or the collection reel 206 may be located within respective load-lock chambers that are evacuated to vacuum conditions. In this case, the insertion point 208 and the removal point 210 may each include an interface for transferring the substrate 203 from one evacuated chamber to another.) The external region 205 of the vacuum chamber 201 may include any region within the vacuum chamber 201 that is not within the container 214, as noted below.

In one example, the substrate 203 is similar to the substrate 100 illustrated in FIG. 1 (or similar to other example substrates discussed with reference to FIG. 1). Initially, at least a portion of the substrate 203 may be rolled up on the feeding reel 204. The substrate 203 may be unfurled by the feeding reel 204 and advanced by the collection reel 206 such that the substrate 203 may be fed through the insertion point 208 and into the vacuum chamber 201. The feeding reel 204 and the collection reel 206 may function to move the substrate 203 over the container 214 with a CIGS surface of the substrate 203 facing down toward the container 214 so that the material 218 may be evaporated onto the substrate 203 as the substrate 203 moves above the container 214. As shown in FIG. 2, the substrate 203 may be moved by the collection reel 206 and the feeding reel 204 along the ‘z’ axis of the container 214. Throughout this disclosure, the ‘z’ axis may be referred to as a second axis of the container 214, but this is an arbitrary convention.

While moving through the vacuum chamber 201, the substrate 203 may be heated by a substrate heater (not shown). The collection reel 206 and the feeding reel 204 may be configured to move the substrate 203 through the vacuum chamber 201 at a rate that allows a predetermined amount of the material 218 to be evaporated onto the substrate 203. The substrate 203 may be removed from the vacuum chamber 201 at the removal point 210, which may include a feedthrough similar to that of the insertion point 208.

The container 214 may be a graphite block machined to include the cavity 216 and the one or more openings 220. In FIG. 2 the cavity 216 is depicted as cylindrical, but the cavity 216 may have other shapes as well. Both the container 214 and the cavity 216 are elongated along a first axis of the container 214. The first axis may be referred to herein as a ‘y’ axis, but this is an arbitrary convention. The cavity 216 may be configured to contain the material 218, such that when the container 214 is heated by the heaters 222 and 224, the material 218 is also heated. The one or more openings 220 may be distributed along the ‘y’ axis of the container and provide fluid communication between the external region 205 and the cavity 216. As used in this disclosure, “fluid communication” may encompass liquid communication and/or vapor communication.

The heaters 222 and 224 are also elongated along the ‘y’ axis and are configured to heat and evaporate the material 218 by heating the container 214. The heaters 222 and 224 may each comprise a pair of graphite blocks machined to dimensions desired. Electric current may be passed through the graphite blocks to generate heat, which may then be radiated toward the container 214. As shown in FIG. 2, the heaters 222 and 224 are located external to the container 214; however, in other examples, the heaters 222 and 224 are electrically isolated from the container and then embedded within the container 214 to heat the container 214 via heat conduction or radiation.

If the heated material were in the external region 205, the vapor pressure of the heated material might quickly reach equilibrium with the ambient pressure of the external region 205. In such a situation, the heated material may transition (i.e., sublimate) directly from a solid phase to a gaseous phase to be deposited upon the substrate 203. However, sublimation of the heated material may result in non-uniform thickness of the material upon the substrate 203. For this reason, evaporation of the material is preferable to sublimation. Evaporation of the material may result from proper temperature and pressure control within the container 214, and having the total cross-sectional area of the one or more openings 220 sized appropriately.

For this reason, the container 214 may be substantially enclosed so as to maintain a pressure differential between the cavity 216 and the external region 205 when the material 218 is heated. For example, the one or more openings 220 may be sized such that when the material 218 is sufficiently heated by the heaters 222 and 224, at least a portion of the material 218 melts from a solid phase into a liquid phase. By fluidly coupling the external region 205 and the cavity 216 with the one or more openings 220, a vapor pressure of the material 218 that is sufficient for evaporation of the material 218 may be maintained. That is, the one or more openings 220 may be sized to restrict flow of vapor of the material 218 such that pressure within the cavity 216 does not reach equilibrium with the evacuated external region 205.

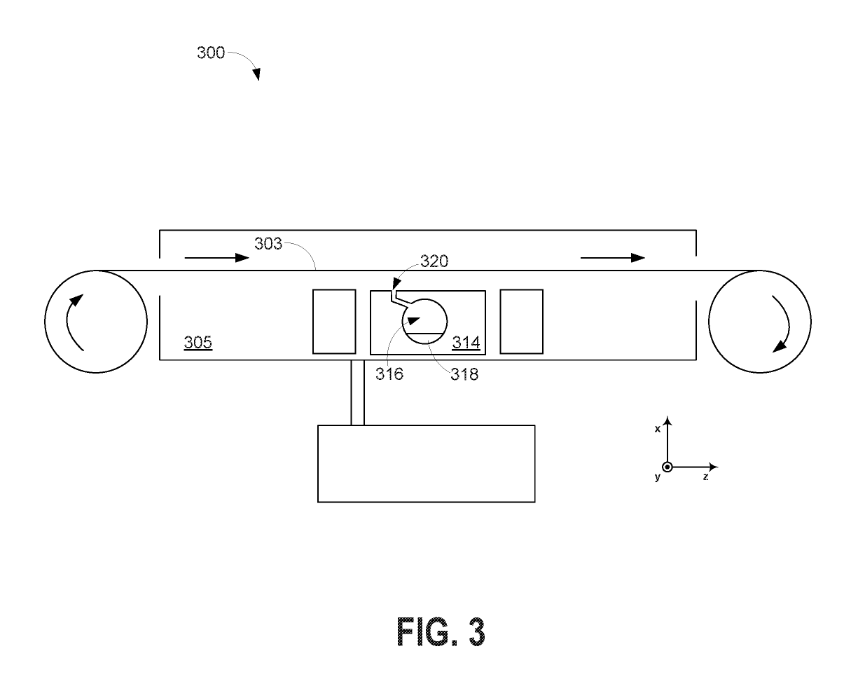

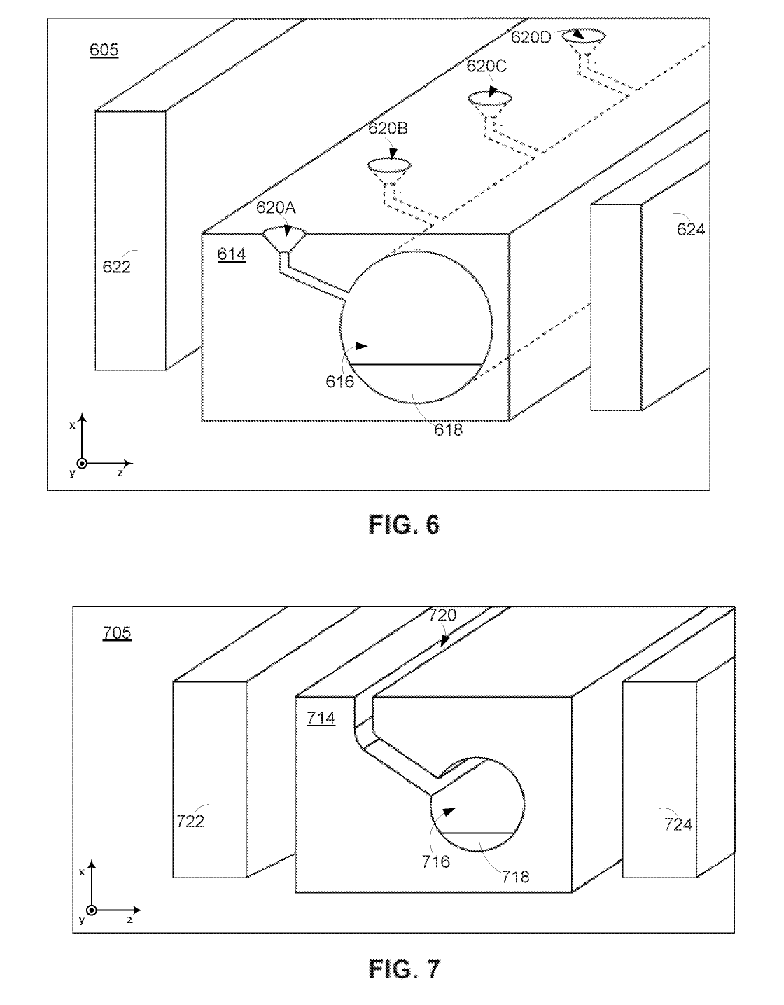

FIG. 3 illustrates another example apparatus 300 for depositing a material 318 onto a substrate 303. Also illustrated in FIG. 3 is a container 314 that includes one or more openings 320. The container 314 may be similar to the container 214 of FIG. 2, except that the one or more openings 320 have different shapes and locations when compared to the one or more openings 220 of FIG. 2. For example, the one or more openings 320 may include elbows or bends that provide fluid communication between the cavity 316 and the external region 305. The one or more openings 320 may also be offset along the ‘z’ axis with respect to the cavity 316. These differences are further explained below with reference to FIGS. 6 and 7.

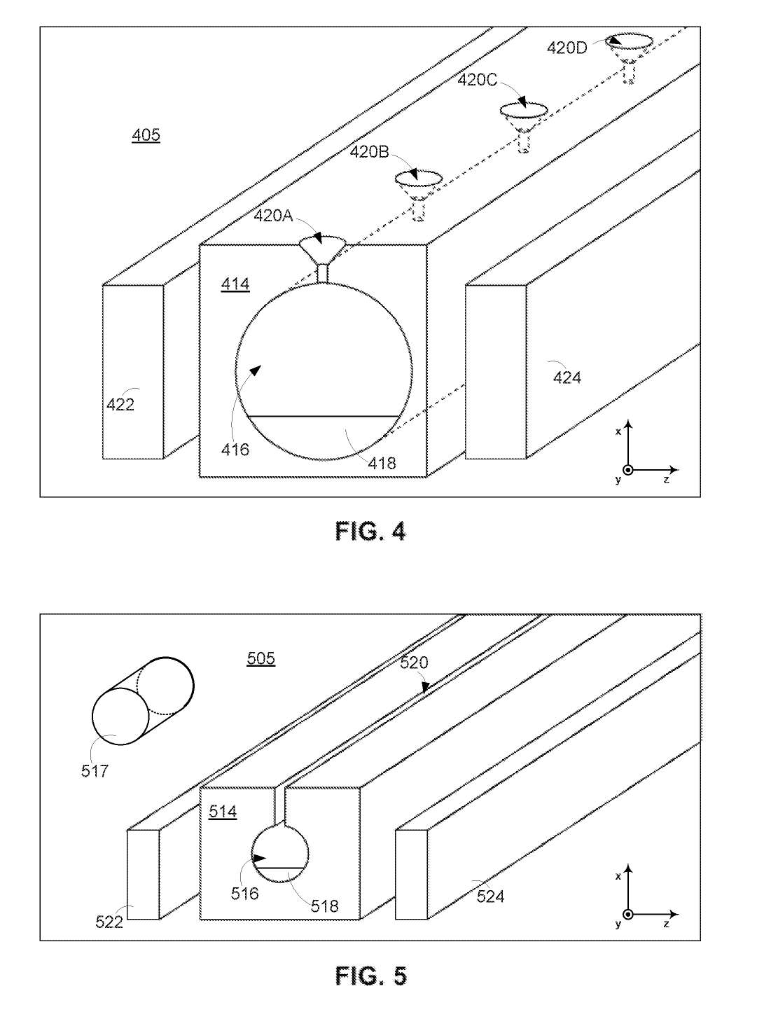

FIG. 4 illustrates an example container 414 and example heaters 422 and 424 for depositing a material 418 onto a substrate (not shown) above the container 414. Also shown in FIG. 4 are openings 420A, 420B, 420C, and 420D that provide fluid communication between the cavity 416 and an external region 405 that is within a vacuum chamber (not shown) yet external to the container 414.

As shown, the container 414 is elongated along the ‘y’ axis of the container 414 to facilitate uniform deposition of the material 418 onto the substrate. The substrate may span the ‘y’ axis and be conveyed along the ‘z’ axis. (See FIGS. 2 and 3 for example substrates.)

As the material 418 is heated by the heaters 422 and 424, at least a portion of the material 418 evaporates and diffuses through the openings 420A-D, into the external region 405, and onto the substrate. The openings 420A-D may be distributed along the ‘y’ axis such that the openings 420A-D have overlapping respective deposition profiles. That is, material 418 that evaporates and passes through the opening 420A may sometimes deposit upon the substrate in the same place where material that evaporated and passed through the opening 420B had also deposited upon the substrate. As shown in FIG. 4, the openings 420A-D may include respective ports at a top exterior surface of the container 414. In some examples, the respective ports may have a conical shape, but other shapes are possible.

FIG. 5 illustrates an example container 514 and example heaters 522 and 524 for depositing a material 518 onto a substrate (not shown) above the container 514. Also shown in FIG. 5 is an opening 520 that provides fluid communication between the cavity 516 and an external region 505 that is within a vacuum chamber (not shown) yet external to the container 514.

The container 514 may differ from the container 414 in that the container 514 includes a single opening 520 that is aligned with the ‘y’ axis. The opening 520 may resemble a rectangular trench that provides fluid communication between the cavity 516 and the external region 505; however other shapes are possible. The vacuum chamber may be evacuated such that vacuum conditions exist in the external region 505. In this context, maintaining a vapor pressure within the cavity 516 that is sufficient for a liquid phase of the material 518 to exist may require that the opening 520 is sized similarly to the openings 420 of FIG. 4. This could mean, for example, that for containers 514 and 414 of similar size, the total cross sectional area of the openings 420 may be substantially equal to the total cross sectional area of the opening 520. As the material 518 is heated by the heaters 522 and 524, at least a portion of the material 518 evaporates and diffuses through the opening 520 and onto the substrate.

Also depicted in FIG. 5 is a plug 517. The plug 517 may be sized appropriately to seal the cavity 516 at a front end of the container 514, and a similar plug may seal the cavity 516 at a back end of the container 514. The plug 517 may be comprised of graphite machined to have a cylindrical shape that fits snugly or threads into the cavity 516 or is configured to seal through any number of other methods. Having the cavity 516 sealed at front and back ends by respective plugs, caps, or other sealing means may result in the opening 520 providing the only fluid communication between the cavity 516 and the external region 505. Similar plugs may also be used to seal front and back ends of the cavities 416 of FIG. 4, as well as cavity 616 of FIG. 6 and cavity 716 of FIG. 7.

FIG. 6 illustrates an example container 614 and example heaters 622 and 624 for depositing a material 618 onto a substrate (not shown) above the container 614. Also shown in FIG. 6 are openings 620A, 620B, 620C, and 620D that provide fluid communication between the cavity 616 and an external region 605 that is within a vacuum chamber (not shown) yet external to the container 614.

As shown in FIG. 6, both heater 622 and heater 624 are adjacent to the container 614 on opposite sides of the container 614. The openings 620A-D may be offset along the ‘z’ axis when compared to the cavity 616. The openings 620A-D may include ports at a top exterior surface of the container 614. As shown, the heater 622 may be closer to the respective ports than to the cavity 616 and the heater 624 may be closer to the cavity 616 than to the respective ports. In some examples, the heater 622 may radiate more heat than the heater 624, causing the evaporated material 618 to experience an increasing temperature gradient as the evaporated material 618 diffuses from the cavity 616 toward the substrate above the container 614. This increasing temperature gradient help prevent the evaporated material 618 from condensing on the walls of the openings 620A-D, which may otherwise disrupt the flow of the evaporated material 618 into the external region 605 and toward the substrate.

FIG. 7 illustrates an example container 714 and example heaters 722 and 724 for depositing a material 718 onto a substrate (not shown) above the container 714. Also shown in FIG. 7 is an opening 720 that provides fluid communication between the cavity 716 and an external region 705 that is within a vacuum chamber (not shown) yet external to the container 714.

As shown in FIG. 7, both heater 722 and heater 724 are adjacent to the container 714 on opposite sides of the container 714. The opening 720 may be offset along the ‘z’ axis when compared to the cavity 716. The opening 720 may include a single port at a top exterior surface of the container 714. As shown, the heater 722 may be closer to the port than to the cavity 716 and the heater 724 may be closer to the cavity 716 than to the port. In some examples, the heater 722 may radiate more heat than the heater 724, causing the evaporated material 718 to experience an increasing temperature gradient as the evaporated material 718 diffuses from the cavity 716, into the external region 705, and toward the substrate above the container 714. This increasing temperature gradient may help prevent the evaporated material 718 from condensing on the walls of the opening 720, which may otherwise disrupt the flow of the evaporated material 718 toward the substrate.

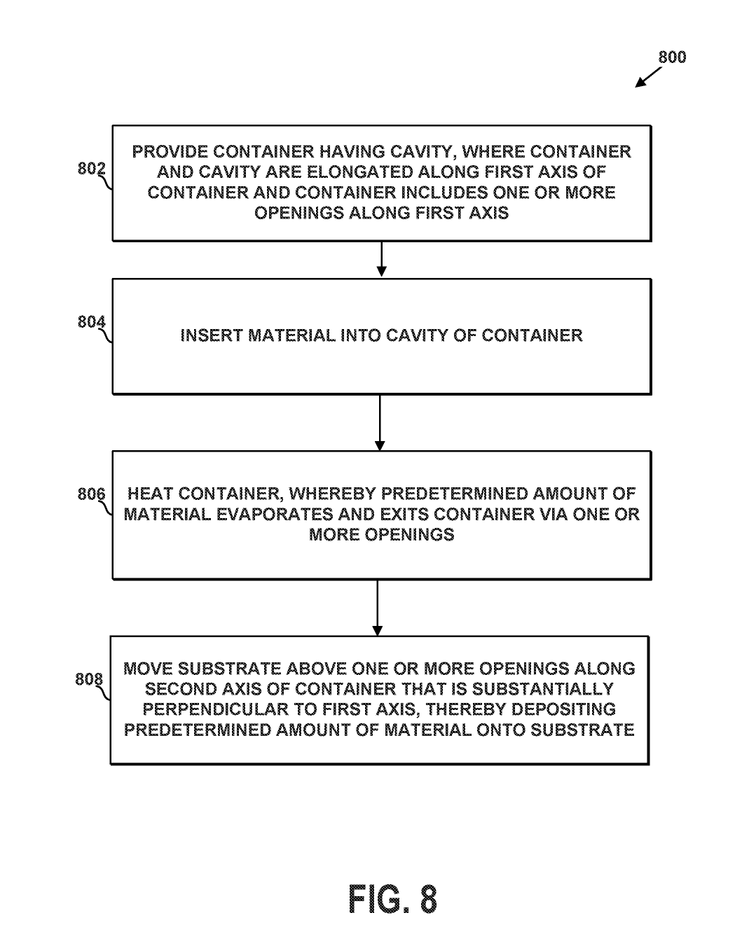

FIG. 8 is a block diagram of an example process 800 for depositing a predetermined amount of a material onto a substrate. In some examples, the material includes mixtures or compounds that include sodium or potassium, such as sodium fluoride (NaF), potassium fluoride (KF), sodium selenide (Na₂Se), or sodium oxide (Na₂O). The container may be formed in whole or in part from graphite. For example, the container may be a graphite block machined to have features such as those of the containers described above with reference to FIGS. 2-7.

At block 802, the process 800 involves providing a container having a cavity. The container and the cavity are elongated along a first axis of the container and the container is located within a vacuum chamber. The container comprises one or more openings distributed along the first axis, where the one or more openings provide fluid communication between the cavity and a region within the vacuum chamber that is external to the container.

Referring to FIG. 2 for example, the container 214 is located within the vacuum chamber 201 and is elongated along the ‘y’ axis. The container includes one or more openings 220 that are distributed along the ‘y’ axis. The one or more openings 220 provide fluid communication between the cavity 216 and the external region 205.

At block 804, the process 800 involves inserting the material into the cavity of the container. In some examples, this includes spooning a powdered material into the cavity of the container, and then placing the container into the vacuum chamber so that the vacuum chamber may be evacuated. In other examples, the container is affixed to the vacuum chamber and the material is inserted into the cavity while the container sits within the vacuum chamber.

At block 806, the process 800 involves heating the container, whereby the predetermined amount of the material evaporates and exits the container via the one or more openings. For example, the container 214 may be heated by the heaters 222 and 224, resulting in a predetermined amount of the material 218 evaporating and exiting the container 214 via the one or more openings 220.

If the one or more openings are sized appropriately and the container is placed within an evacuated vacuum chamber, heating the container causes at least some of the material to form a liquid phase inside of the cavity. That is, the one or more openings may be sized to restrict the flow of vapor of the material such that an elevated vapor pressure of the material is maintained within the cavity.

In some examples, heating the container may involve heating the container with one or more heaters that are elongated along the first axis of the container, as described above with reference to FIGS. 2-7. Such heaters are located external to the container. In other embodiments, the heaters are embedded within the container.

In other examples, heating the container may involve heating the container with a heater that is adjacent to the container, where the one or more openings comprise respective ports at an exterior surface of the container, and where the heater is closer to the respective ports than to the cavity. Referring to FIG. 6 for example, the heaters 622 and 624, which are adjacent to the container 614, may heat the container 614. The heater 622 may be closer to the ports respectively corresponding to the openings 620A-D than to the cavity 616.

In this context, heating the container may involve heating a portion of the container proximate to the respective ports to a first temperature, and heating a portion of the container proximate to the cavity to a second temperature that is less than the first temperature.

The container 614 may include one or more openings 620A-D and respective ports that are located on the top exterior surface of the container 614. The heater 622 may be set to radiate more heat than the heater 624, and as a result, regions of the container 614 that are near the respective ports may be heated to a higher temperature than regions of the container near the cavity 616. This may result in the evaporated material 618 experiencing an increasing temperature gradient as the evaporated material 618 diffuses from the cavity 616 to the external region 605, through the one or more openings 620A-D.

In another example, the heaters 622 and 624 may be set to radiate roughly equal amounts of power, but the distance separating the heater 622 and the respective ports may be less than the distance separating the heater 624 and the cavity 616. This may also result in the evaporated material 618 experiencing an increasing temperature gradient as the evaporated material 618 diffuses from the cavity 616 to the external region 605, through the one or more openings 620A-D.

At block 808, the process 800 involves moving the substrate above the one or more openings along a second axis of the container that is substantially perpendicular to the first axis, thereby depositing the predetermined amount of the material onto the substrate. For example, the substrate 203 may be moved above the one or more openings 220 along the ‘z’ axis, which is perpendicular to the ‘y’ axis along which the cavity 216 and the container 214 are elongated.

The above detailed description describes various features and functions of the disclosed systems and processes with reference to the accompanying figures. While various aspects and embodiments have been disclosed herein, other aspects and embodiments will be apparent to those skilled in the art. All embodiments within and between different aspects of the invention can be combined unless the context clearly dictates otherwise. The various aspects and embodiments disclosed herein are for purposes of illustration and are not intended to be limiting, with the true scope and spirit being indicated by the following claims.

1. A process for depositing a predetermined amount of a material onto a substrate, the process comprising:
providing a container having a cavity, wherein the container and the cavity are elongated along a first axis of the container, wherein the container is located within a vacuum chamber, and wherein the container comprises:
one or more openings distributed along the first axis, wherein the one or more openings provide fluid communication between the cavity and a region within the vacuum chamber that is external to the container and wherein the one or more openings are sized to restrict flow of vapor of the material such that pressure within the cavity does not reach equilibrium with the pressure in the region within the vacuum chamber that is external to the container;
inserting the material into the cavity of the container;
heating the container, whereby the predetermined amount of the material evaporates and exits the container via the one or more openings; and
moving the substrate above the one or more openings along a second axis of the container that is substantially perpendicular to the first axis, thereby depositing the predetermined amount of the material onto the substrate.

2. The process of claim 1, wherein the material comprises sodium or potassium.

3. The process of any of claim 1, wherein heating the container further causes at least some of the material to form a liquid phase inside of the cavity.

4. The process of claim 1, wherein heating the container comprises heating the container with one or more heaters that are elongated along the first axis of the container.

5. The process of claim 1, wherein heating the container comprises heating the container with one or more heaters located external to the container.

6. The process of claim 1, wherein heating the container comprises heating the container with a heater that is adjacent to the container, wherein the one or more openings comprise respective ports at an exterior surface of the container, and wherein the heater is closer to the respective ports than to the cavity.

7. The process of claim 1, wherein the one or more openings comprise respective ports at an exterior surface of the container, and wherein heating the container comprises:
heating a portion of the container proximate to the respective ports to a first temperature; and
heating a portion of the container proximate to the cavity to a second temperature that is less than the first temperature.

8. The process of any claim 1, wherein the container comprises graphite.

9. An apparatus for depositing a predetermined amount of a material onto a substrate, the apparatus comprising:
a container having a cavity configured to contain the material, wherein the container and the cavity are elongated along a first axis of the container;
one or more heaters that are (i) elongated along the first axis and (ii) configured to heat and evaporate the material by heating the container;
a conveyor for moving the substrate in a direction substantially perpendicular to the first axis of the container; and
one or more openings in the container distributed along the first axis, wherein the one or more openings provide fluid communication between a region external to the container and the cavity and wherein the one or more openings are sized to restrict flow of vapor of the material such that pressure within the cavity does not reach equilibrium with the pressure in the region within the vacuum chamber that is external to the container.

10. The apparatus of claim 9, wherein the cavity comprises an opening at an end of the cavity, the apparatus further comprising a plug configured to seal the opening.

11. The apparatus of claim 9, wherein the one or more heaters are located external to the container.

12. The apparatus of claim 9, wherein at least one of the one or more heaters comprises a graphite heating element.

13. The apparatus of claim 9, wherein the one or more heaters comprise a given heater that is adjacent to the container, wherein the one or more openings comprise respective ports at an exterior surface of the container, and wherein the given heater is closer to the respective ports than to the cavity.

14. The apparatus of claim 13, wherein the given heater is a first heater located adjacent to the container on a first side of the container, wherein the one or more heaters further comprise a second heater adjacent to the container on a second side of the container that is opposite the first side, and wherein the second heater is closer to the cavity than to the respective ports.

15. The apparatus of claim 9, wherein the container comprises graphite.

16. The process of any of claim 2, wherein heating the container further causes at least some of the material to form a liquid phase inside of the cavity.

17. The process of claim 16, wherein heating the container comprises heating the container with one or more heaters that are elongated along the first axis of the container.

18. The process of claim 17, wherein heating the container comprises heating the container with one or more heaters located external to the container.

19. The process of claim 18, wherein heating the container comprises heating the container with a heater that is adjacent to the container, wherein the one or more openings comprise respective ports at an exterior surface of the container, and wherein the heater is closer to the respective ports than to the cavity.

20. The process of claim 19, wherein the one or more openings comprise respective ports at an exterior surface of the container, and wherein heating the container comprises:
heating a portion of the container proximate to the respective ports to a first temperature; and
heating a portion of the container proximate to the cavity to a second temperature that is less than the first temperature.
